(19) United States
(12) Patent Application Publication
(10) Pub. No.: US 2010/0224983 A1
(43) Pub. Date: Sep. 9, 2010

(54) SEMICONDUCTOR PACKAGE STRUCTURE AND MANUFACTURING METHOD THEREOF

(76) Inventors: Min-Lung Huang, Kaohsiung City (TW); Chih-Yuan Cheng, Pingtung City (TW)

Correspondence Address: COOLEY LLP;ATTN: Patent Group, Suite 1100, 777 - 6th Street, NW, WASHINGTON, DC, 20001, US

(21) Appl. No.: 12/625,848

(22) Filed: Nov. 25, 2009

(30) Foreign Application Priority Data
Mar. 3, 2009 (TW) 98106892

(51) Int. Cl. H01L 23/36; H01L 23/48; H01L 21/78

(52) U.S. Cl. 257/692; 438/113; 257/712; 438/124; 257/E21.504; 257/E21.599; 257/E23.01; 257/E23.101

(57) ABSTRACT

A manufacturing method of a semiconductor package structure includes the following steps. Firstly, a carrier having an adhesion tape is provided. Next, a plurality of chips are disposed on the adhesion tape. Then, a molding compound is dispensed on the adhesion tape, so that the molding compound covers the chips. Afterwards, a heat spreader is disposed on a plurality of chips. Then, the molding compound is solidified as an encapsulant to fix the heat spreader on the chips. After that, the carrier and the adhesion tape are removed to expose the active surfaces of the chips. Then, a redistribution layer is formed adjacent to the active surfaces of the chips. Next, a plurality of solder balls are disposed on the redistribution layer. Lastly, a plurality of packages are formed by cutting the redistribution layer, the encapsulant and the heat spreader according to the positions of the chip.

This application claims the benefit of Taiwan application Serial No. 98106892, filed Mar. 3, 2009, the subject matter of which is incorporated herein by reference.

### BACKGROUND

1. Technical Field

The disclosure relates in general to a semiconductor package structure and a manufacturing method thereof, and more particularly to a semiconductor package structure having a heat spreader and a manufacturing method thereof.

2. Description of the Related Art

In recent years, electronic devices are widely used in people's daily lives, and the manufacturers are dedicated to provide miniaturized and multi-functional electronic products to meet the market demands. Currently, wafer level package (WLP) is a package structure commonly used in the semiconductor elements of an electronic product.

The dimension of the product becomes smaller and smaller but the function is more and more diversified. To make the chip function properly, the heat generated during the operation of the chip must be dissipated effectively to avoid the internal circuits being damaged and prevent the efficiency and the function of the chip from being affected when the temperature of the chip is too high.

### SUMMARY

The disclosure is directed to a semiconductor package structure and a manufacturing method thereof. The encapsulant is used for fixing the heat spreader on the chip directly during a solidifying process.

According to a first aspect of the present disclosure, a semiconductor package structure is provided. The semiconductor package structure includes a chip, a heat spreader, an encapsulant, a redistribution layer, and a plurality of solder balls. The encapsulant covers the chip and fixes the heat spreader on the chip. The chip has an active surface and a rear surface, the heat spreader is disposed adjacent to the rear surface of the chip, and the redistribution layer is disposed adjacent to the active surface of the chip. The solder balls are disposed on the redistribution layer.

According to a second aspect of the present disclosure, a manufacturing method of a semiconductor package structure is provided. The method includes the following steps. Firstly, a carrier having an adhesion tape is provided. Next, a plurality of chips are disposed on the adhesion tape. Then, a molding compound is dispensed on the adhesion tape, so that the molding compound covers the chips. Afterwards, a heat spreader is disposed on a plurality of chips. Then, the molding compound is solidified as an encapsulant to fix the heat spreader on the chips. After that, the carrier and the adhesion tape are removed to expose the active surfaces of the chips. Then, a redistribution layer is formed adjacent to the active surfaces of the chips. Next, a plurality of solder balls are disposed on the redistribution layer. Lastly, a plurality of packages are formed by cutting the redistribution layer, the encapsulant and the heat spreader according to the positions of the chips.

The disclosure will become apparent from the following detailed description of the preferred but non-limiting embodiments. The following description is made with reference to the accompanying drawings.

### BRIEF DESCRIPTION OF THE DRAWINGS

FIG. 1A shows a semiconductor package structure according to a first embodiment of the disclosure;

FIG. 1B shows a semiconductor package structure according to a second embodiment of the disclosure;

FIG. 2A˜2L show a manufacturing method of a semiconductor package structure according to a first embodiment of the disclosure; and

FIG. 3A˜3K show a manufacturing method of a semiconductor package structure according to a second embodiment of the disclosure.

### DETAILED DESCRIPTION

### First Embodiment

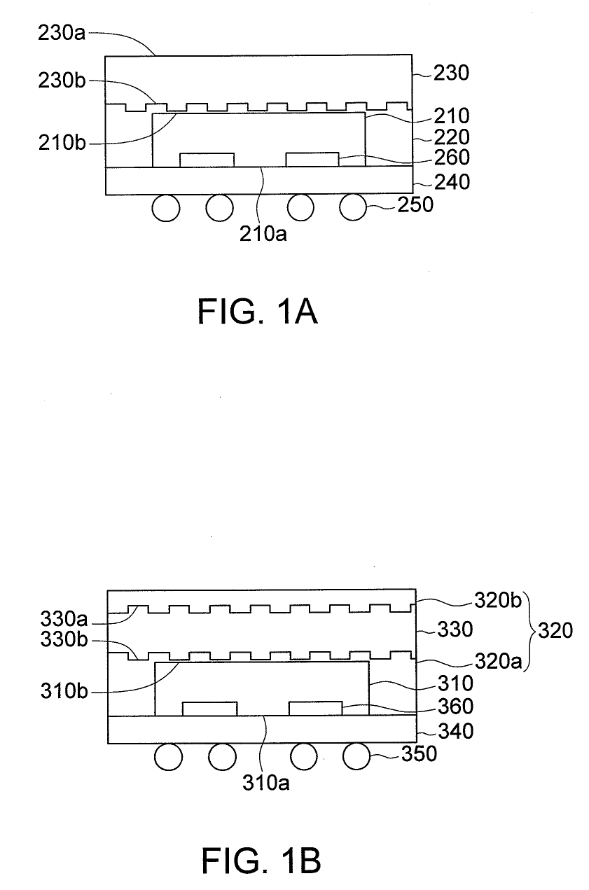

Referring to FIG. 1A, a semiconductor package structure according to a first embodiment of the disclosure is shown. The semiconductor package structure of FIG. 1A includes a chip 210, a heat spreader 230, an encapsulant 220, a redistribution layer 240, a plurality of solder balls 250 and a plurality of solder pads 260. The encapsulant 220 covers the chip 210 and fixes the heat spreader 230 on the chip 210. The chip 210 has an active surface 210a and a rear surface 210b. The redistribution layer 240 is disposed adjacent to the active surface 210a of the chip 210. The heat spreader 230 is disposed adjacent to the rear surface 210b of the chip 210, and preferably is fixed on the rear surface 210b of the chip 210. The solder balls 250 are disposed on the redistribution layer 240. The solder pads 260 are disposed on the active surface 210a of the chip 210.

The heat spreader 230 has a heat-spreading surface 230a and a bonding surface 230b opposite to the heat-spreading surface 230a. As indicated on FIG. 1A, the bonding surface 230b is a rough surface for increasing the adhesion between the bonding surface 230b and the encapsulant 220 so that the heat spreader 230, the encapsulant 220 and the chip 210 are tightly bonded. The bonding surface 230b of the heat spreader 230 faces the rear surface 210b of the chip 210, and the area of the bonding surface 230b is larger than that of the rear surface 210b. In the present embodiment of the disclosure, the heat-spreading surface 230a of the heat spreader 230 is exposed in the air for increasing heat dissipation efficiency and facilitating the subsequent printing or coating process.

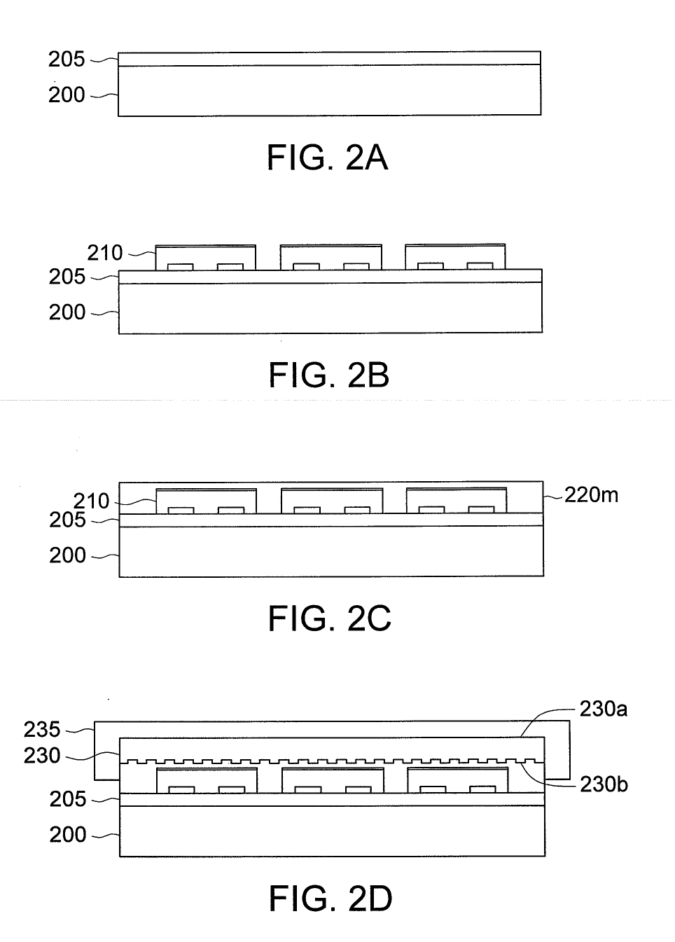

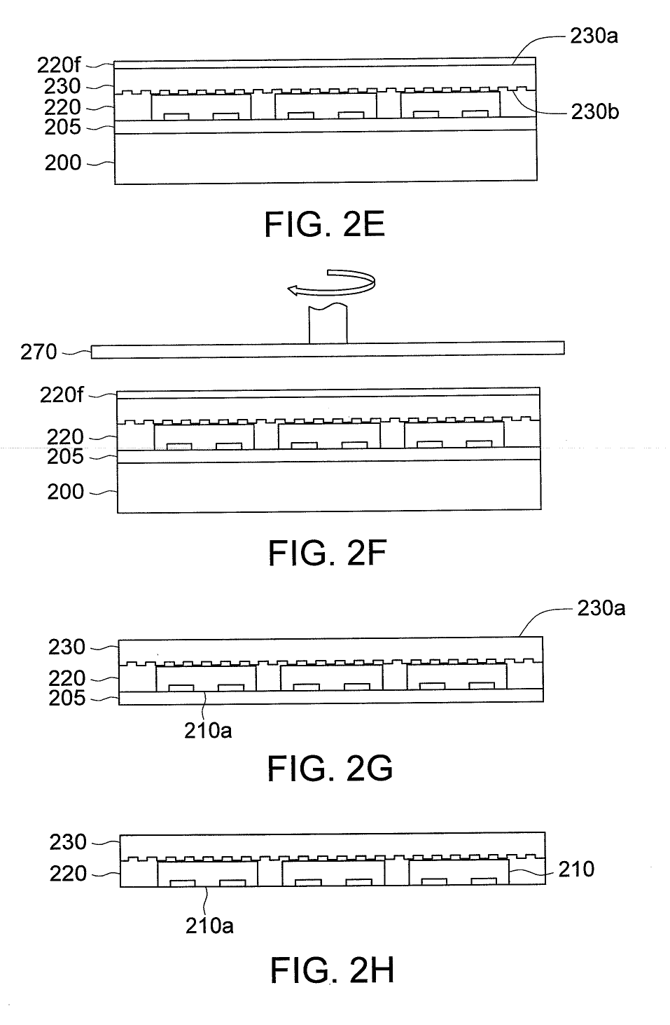

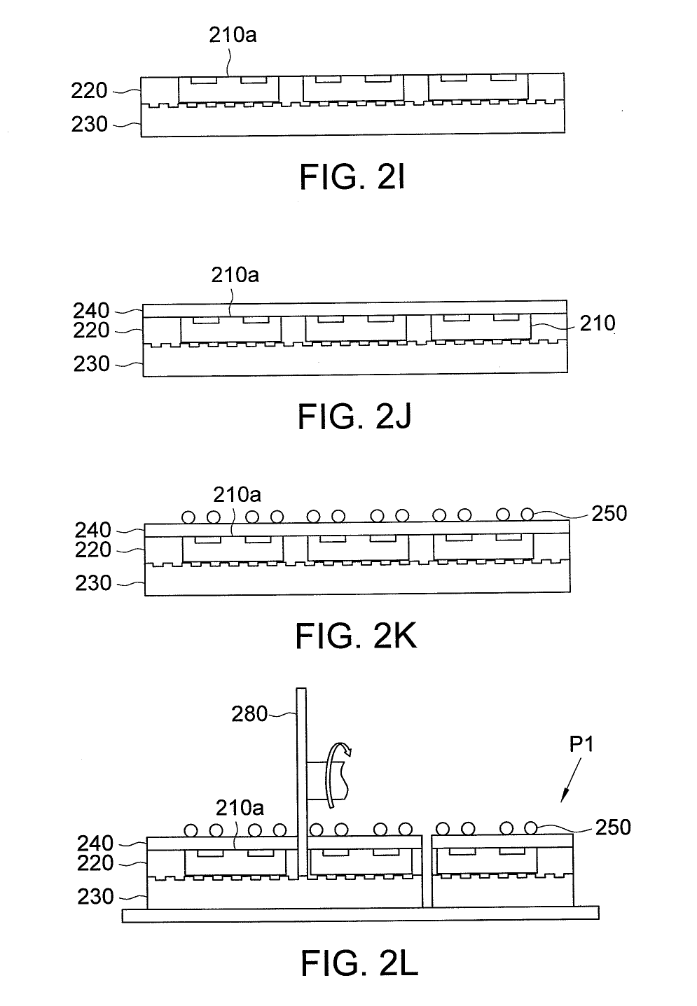

FIG. 2A˜2L show a manufacturing method of a semiconductor package structure according to a first embodiment of the disclosure. Firstly, in FIG. 2A, a carrier 200 having an adhesion tape 205 is provided. Both surfaces of the adhesion tape 205 have adhesion, and one of the two surfaces is pasted on the carrier 200.

Next, in FIG. 2B, a plurality of chips 210 are disposed on the adhesion tape 205. As the other surface of the adhesion tape 205 also has adhesion, a plurality of chips 210 are directly pasted on the other surface of the adhesion tape 205.

As indicated on FIG. 2C, a molding compound 220m is disposed on the adhesion tape 205, so that the molding compound 220m covers a plurality of chips 210. The step of disposing the molding compound 220m is preferably performed by way of dispensing.

FIG. 2C and FIG. 2D show a practical method of fixing a heat spreader 230 on a package structure. The heat spreader 230 is disposed on a plurality of chips 210. The molding compound 220m is solidified to be an encapsulant 220 so as to fix the heat spreader 230 on a plurality of chips 210. The solidifying process can be further divided into a first solidifying stage and a second solidifying stage.

In the first solidifying stage, the molding compound 200 is heated so that the molding compound 220m is in a semi-solidified state. When the molding compound 220m is heated and becomes semi-solidified, the heat spreader 230 is disposed on a plurality of chips 210. In the step of disposing the heat spreader 230, the present method further includes the following sub-step. A mold 235 is provided and is further aligned with the carrier 200, so that the mold 235 covers the molding compound 200m and the heat spreader 230. Meanwhile, the mold 235 is pressed downwardly, so that the molding compound 200m is spread over the bonding surface 230b of the heat spreader 230 and a part of the molding compound 200m fills the heat-spreading surface 230a of the heat spreader 230. Then, a mold releasing process is performed for releasing the mold 235.

In the second solidifying stage, the molding compound 220m is continually heated to completely solidify the molding compound 220m to be an encapsulant 220. The molding compound 220m, once solidified to be an encapsulant, is capable of firmly fixing the heat spreader 230 on the chips 210. As indicated on FIG. 2E, the encapsulant 220 is disposed under the bonding surface 230b of the heat spreader 230, and the molding compound 220f which is already solidified and left on the heat-spreading surface of the heat spreader 230a fills to the molding compound 220m of the heat-spreading surface 230a during the manufacturing process.

Next, in FIG. 2F, the manufacturing method of the present embodiment of the disclosure further includes the sub-step of grinding the molding compound 220f left on the heat-spreading surface 230a by the grinding facility 270. After the grinding process is completed, the heat-spreading surface 230a is exposed in the air as indicated on FIG. 2G. Then, the carrier 200 and the adhesion tape 205 are subsequently remove to expose the active surfaces 210a of a plurality of chips 210 as indicated on FIG. 2H.

In FIG. 2I, the entire structure is turned over upside down so as to form a redistribution layer 240 adjacent to the active surfaces of 210a of the chip 210 in FIG. 2J. Next, in FIG. 2K, a plurality of solder balls 250 are disposed on the redistribution layer 240.

Lastly, in FIG. 2L, a plurality of packages P1 are formed by cutting the redistribution layer 240, the encapsulant 220 and the heat spreader 230 with the cutting tool 280 according to a plurality of the chip 210.

### Second Embodiment

The present embodiment of the disclosure mainly differs with the first embodiment in the space relationship between the molding compound and the heat spreader and in the omission of the grinding process.

Referring to FIG. 1B, a semiconductor package structure according to a second embodiment of the disclosure is shown. The semiconductor package structure of FIG. 1B includes a chip 310, a heat spreader 330, an encapsulant 320, a redistribution layer 340, a plurality of solder balls 350 and a plurality of solder pads 360. The encapsulant 320 covers the chip 310 and fixed the heat spreader 330 on the chip 310. The encapsulant 320 includes a first encapsulant 320a and a second encapsulant 320b respectively disposed on the bonding surface 330b and the heat-spreading surface 330a of the heat spreader 330. The chip 310 has an active surface 310a and a rear surface 310b. The redistribution layer 340 is disposed adjacent to the active surfaces 310a of the chip 310. The heat spreader 330 is adjacent to the rear surface 310b of the chip 310 and preferably is fixed on the rear surface 310b of the chip 310. A plurality of solder balls 350 are disposed on the redistribution layer 340. The solder pads 360 are disposed on the active surface 310a of the chip 310.

The heat spreader 330 has a heat-spreading surface 330a and a bonding surface 330b opposite to the heat-spreading surface 330a. As indicated on FIG. 1B, the bonding surface 330b is a rough surface for increasing the adhesion between the bonding surface 330b and the first encapsulant 320a so that the heat spreader 330, the first encapsulant 320a and the chip 310 are tightly bonded. Besides, the heat-spreading surface 330a of the heat spreader 330 can also be a rough surface for increasing the adhesion between the heat-spreading surface 330a and the second encapsulant 320b so that the heat spreader 330 and the second encapsulant 320b are tightly bonded. The bonding surface 330b of the heat spreader 330 faces the rear surface 310b of the chip 310, and the area of the bonding surface 330b is larger than that of the rear surface 310b. Compared with the first embodiment, the heat-spreading surface 330a of the heat spreader 330 of the present embodiment of the disclosure further covers a second encapsulant 320b, not only enhancing the encapsulant 320 in fixing the heat spreader 330 but also omitting the subsequent printing or coating process in the manner that a cutting process is directly applied to the second encapsulant 320b by way of laser.

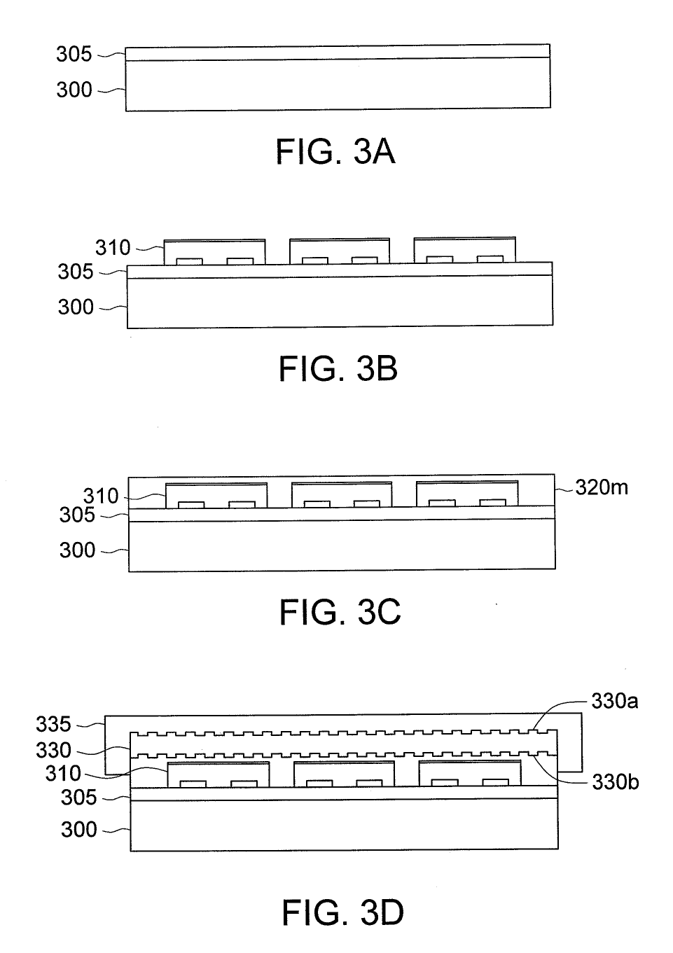

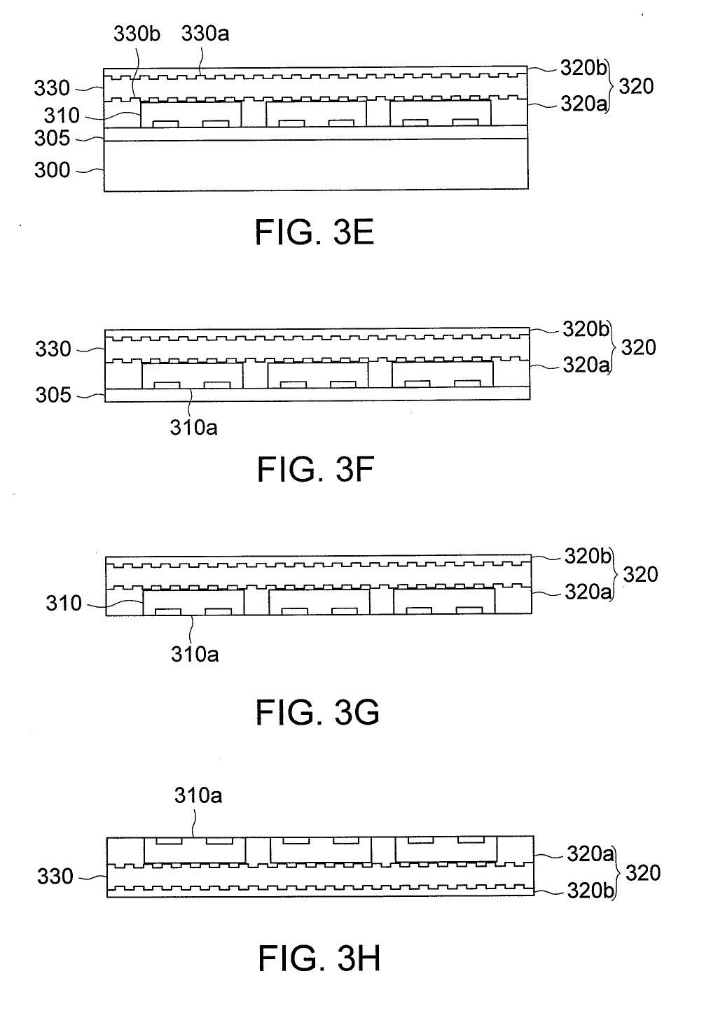

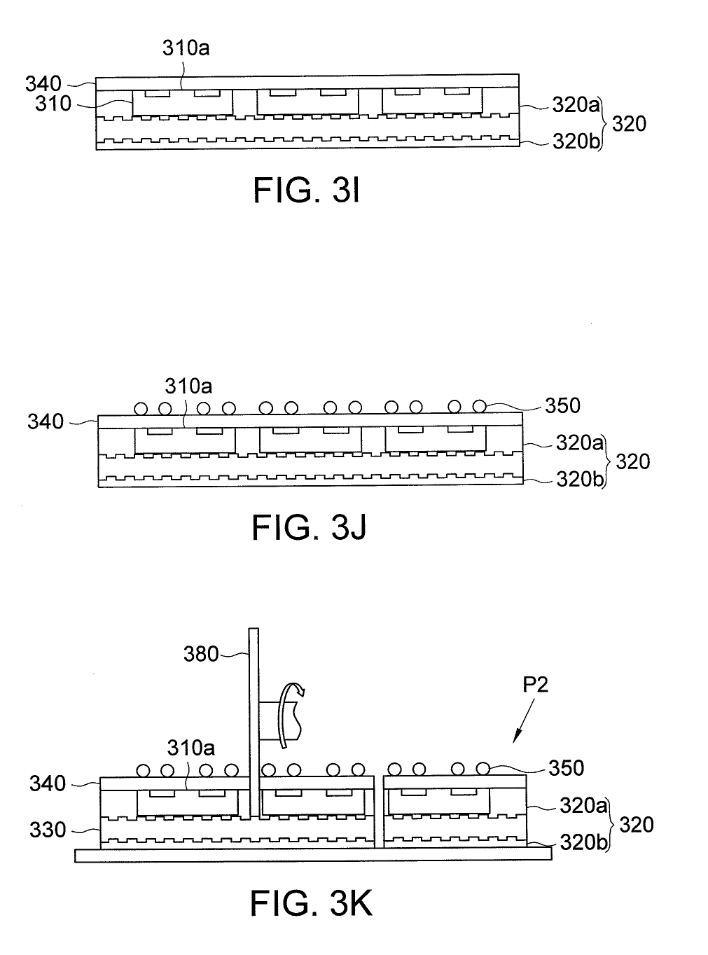

FIG. 3A˜3L shows a manufacturing method of a semiconductor package structure according to a second embodiment of the disclosure. Firstly, in FIG. 3A, a carrier 300 having an adhesion tape 305 is provided. Both surfaces of the adhesion tape 305 have adhesion, and one of the two surfaces is pasted on the carrier 300.

Next, in FIG. 3B, a plurality of chips 310 are disposed on the adhesion tape 305. As the other surface of the adhesion tape 305 also has adhesion, a plurality of chips 310 are directly pasted on the other surface of the adhesion tape 305.

As indicated on FIG. 3C, a molding compound 320m is disposed on the adhesion tape 305, so that the molding compound 320m covers a plurality of chips 310. The step of disposing the molding compound 320m is preferably performed by way of dispensing.

FIG. 3C and FIG. 3D show a practical method of fixing a heat spreader 330 on a package structure. A heat spreader 330 is disposed on a plurality of chips 310, the molding compound 320m is solidified to be an encapsulant 320 so as to fix the heat spreader 330 on the chips 310. The solidifying process can be further divided into a first solidifying stage and a second solidifying stage.

In the first solidifying stage, the molding compound 300 is heated so that the molding compound 320m is in a semi-solidified state. When the molding compound 320m is heated and becomes semi-solidified, the heat spreader 330 is disposed on a plurality of chips 310. In the step of disposing the heat spreader 330, the present method further includes the following sub-step. A mold 335 is provided and is further aligned with the carrier 300, so that the mold 335 covers the molding compound 300m and the heat spreader 330. Meanwhile, the mold 335 is pressed downwardly, so that the molding compound 300m is spread over the bonding surface 330b of the heat spreader 330 and a part of the molding compound 300m fills the heat-spreading surface 330a of the heat spreader 330. Then, a mold releasing process is performed for releasing the mold 335.

In the second solidifying stage, the molding compound 320m is continually heated to completely solidify the molding compound 320m to be an encapsulant 320. The molding compound 320m once solidified to be an encapsulant is capable of firmly fixing the heat spreader 330 on the chip 310. As indicated on FIG. 3E, the encapsulant 320 includes a first encapsulant 320a disposed under the bonding surface 330b of the heat spreader 330 and a second encapsulant 320b disposed on the heat-spreading surface of the heat spreader 330a. The second encapsulant 320b is formed by the molding compound 320m which fills the heat-spreading surface 330a during the manufacturing process.

Compared with the first embodiment, the present embodiment of the disclosure omits the grinding process but reserves the second encapsulant 320b formed by the molding compound 320m when filling the heat-spreading surface 330a. Thus, both the heat-spreading surface 330a and the bonding surface 330b of the heat spreader 330 cover the solidified molding compound so that the heat spreader 330 is more firmly fixed.

Then, the carrier 300 is removed in FIG. 3E and the adhesion tape 305 is removed in FIG. 3F to expose the active surfaces of 310a of a plurality of chips 310 as indicated on FIG. 3G.

Then, in FIG. 3H, the entire structure is turned upside down so as to form a redistribution layer 340 adjacent to the active surfaces 310a of a plurality of chips 310 in FIG. 3I. Next, in FIG. 3J, a plurality of solder balls 350 are disposed on the redistribution layer 340.

Lastly, in FIG. 3K, a plurality of packages P2 are formed by cutting the redistribution layer 340, the first encapsulant 320a, the heat spreader 330 and the second encapsulant 320b with the cutting tool 380 according to the positions of a plurality of chips 310.

According to the semiconductor package structure and the manufacturing method thereof disclosed in the above embodiments of the disclosure, an encapsulant is used for fixing the heat spreader on the chip directly in a solidifying process, so that there is no need to bond the heat spreader and the chip together with a heat-dissipating adhesive. Thus, the manufacturing cost is reduced as the adhering process is avoided. Moreover, the rough surface of the heat spreader increases the adhesion between the surface and the encapsulant, and this is conducive for the subsequent cutting process. Besides, by fixing the heat spreader with an encapsulant directly, the thickness of the entire package is reduced by the thickness of the heat-dissipating adhesive, further increasing product competiveness.

While the disclosure has been described by way of example and in terms of a preferred embodiment, it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package structure, comprising:
a chip having an active surface and a rear surface;
a heat spreader disposed adjacent to the rear surface of the chip;
an encapsulant for covering the chip and fixing the heat spreader on the chip;
a redistribution layer (RDL) disposed adjacent to the active surface of the chip; and
a plurality of solder balls disposed on the redistribution layer.

2. The package structure according to claim 1, wherein the heat spreader has a heat-spreading surface and a bonding surface opposite to the heat-spreading surface.

3. The package structure according to claim 2, wherein the bonding surface is a rough surface, so that the heat spreader, the encapsulant and the chip are tightly bonded.

4. The package structure according to claim 2, wherein the heat-spreading surface of the heat spreader is exposed in the air.

5. The package structure according to claim 2, wherein the encapsulant comprises a first encapsulant and a second encapsulant respectively disposed on the bonding surface and the heat-spreading surface of the heat spreader.

6. The package structure according to claim 5, wherein the heat-spreading surface is a rough surface, so that the heat spreader and the second encapsulant are tightly bonded.

7. The package structure according to claim 6, wherein both the heat-spreading surface and the bonding surface are a rough surface, so that the second encapsulant, the heat spreader, the first encapsulant and the chip are tightly bonded in sequence.

8. The package structure according to claim 1, wherein the heat spreader is fixed on the rear surface of the chip.

9. The package structure according to claim 8, wherein a bonding surface of the heat spreader faces the rear surface of the chip, and an area of the bonding surface is larger than that an area of the rear surface.

10. The package structure according to claim 1, further comprising:
a plurality of solder pads disposed on the active surface of the chip.

11. A manufacturing method of a semiconductor package structure, wherein the method includes the following steps:
providing a carrier having an adhesion tape;
disposing a plurality of chips on the adhesion tape;
disposing a molding compound on the adhesion tape, so that the molding compound covers the chips;
disposing a heat spreader on the chips;
solidifying the molding compound to be an encapsulant so as to fix the heat spreader on the chips;
removing the carrier and the adhesion tape to expose the active surfaces of the chips;
forming a redistribution layer adjacent to the active surfaces of the chips;
disposing a plurality of solder balls on the redistribution layer; and
forming a plurality of packages by cutting the redistribution layer, the encapsulant and the heat spreader according to positions of the chips.

12. The manufacturing method according to claim 11, wherein the solidifying step comprises:
heating the molding compound to semi-solidify the molding compound; and
continuously heating the molding compound to completely solidify the molding compound to be the encapsulant.

13. The manufacturing method according to claim 12, wherein the heat spreader is disposed on the chips when the molding compound is heated to be semi-solidified.

14. The manufacturing method according to claim 12, wherein the encapsulant firmly fixes the heat spreader on the chips when the molding compound is heated and solidified to be the encapsulant completely.

15. The manufacturing method according to claim 11, wherein in the step of disposing the heat spreader, the method further comprises:
providing a mold;
aligning the mold with the carrier, so that the mold covers the molding compound and the heat spreader;
pressing the mold downwardly, so that the molding compound is spread over a bonding surface of the heat spreader and fills a heat-spreading surface of the heat spreader; and
applying mold releasing process for releasing the mold.

16. The manufacturing method according to claim 15, wherein the method further comprises:
grinding the molding compound left on the heat-spreading surface for exposing the heat-spreading surface in the air.

17. The manufacturing method according to claim 11, wherein the heat spreader has a bonding surface facing the chips, and the bonding surface is a rough surface for providing a force so that the heat spreader, the encapsulant and the chips are tightly bonded after the step of solidifying the molding compound.

18. The manufacturing method according to claim 17, wherein the heat spreader has a heat-spreading surface opposite to the bonding surface, and the heat-spreading surface is another rough surface, so that the heat spreader and the encapsulant are tightly bonded after the step of solidifying the molding compound.

19. The manufacturing method according to claim 11, wherein the step of disposing the molding compound is performed by way of dispensing.

20. The manufacturing method according to claim 11, further comprising:
disposing a plurality of solder pads on the active surfaces of the chips.
